(19) United States
(12) Patent Application Publication
(10) Pub. No.: US 2009/0231165 A1
(43) Pub. Date: Sep. 17, 2009

(54) DETECTION CIRCUIT FOR DETECTING MOVEMENTS OF A MOVABLE OBJECT

(75) Inventor: Kim Phan Le, Waalre (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/301,302

(22) PCT Filed: May 8, 2007
(86) PCT No.: PCT/IB2007/051722

§ 371 Date: Nov. 18, 2008

(30) Foreign Application Priority Data
May 19, 2006 (EP) 06114268.3

(51) Int. Cl. H03K 17/94

(52) U.S. Cl. 341/20

(57) ABSTRACT

Detection circuits (1) for detecting movements of movable objects (2) such as joysticks are provided with first detectors (100) for detecting first movements of the joysticks in first directions, comprising first detection units (101) for detecting a presence/absence of light spots (3), locations of the light spots (3) depending on said first movements, and with second detectors (200) for detecting second movements of the joysticks in second directions, comprising second detection units (201) for detecting first/second intensities of the light spots (3), intensities of the light spots (3) depending on said second movements. Such detection circuits (1) are less sensitive to misalignment of components during an assembly and simpler to produce and less costly. The second detectors (200) are entirely located within the light spot (3) independently from positions of the joysticks and the first and third detectors are partly located within the light spot (3) dependently on positions of the joysticks. The detection units (101) comprise photo diodes (120) and transistors (121) for digitizing the signals from the photo diodes (120).

The invention relates to a detection circuit for detecting movements of a movable object, and also relates to a detection arrangement, to a device and to a method.

Examples of such a movable object are joysticks and multi functional keys, and examples of such a device are consumer products, such as mobile phones, personal computers, personal digital assistants and remote controls, and non-consumer products, without excluding further examples.

A prior art detection arrangement is known from U.S. Pat. No. 6,326,948, which discloses an input device comprising a base with a slide surface, a movable body slidable on the slide surface, a light emitting element for emitting light, a reflective portion which is provided for the movable body and has a reflective surface for reflecting the light emitted by the light emitting element, and a plurality of light receiving elements for receiving the light reflected by the reflective portion.

In the prior art detection arrangement, horizontal movements are detected by comparing amounts of light received by the plurality of light receiving elements. To detect vertical movements, a diaphragm is placed between the movable body and the light receiving elements, such that a size of a light spot on the light receiving elements increases when the movable body is pushed down. The vertical movements are therefore detected by detecting a total amount of light received by the plurality of light receiving elements.

The known detection arrangement is disadvantageous, inter alia, owing to the fact that it requires a diaphragm to be able to detect vertical movements. Such a diaphragm is sensitive to misalignment of components during an assembly and makes a production more complex and more expensive.

It is an object of the invention, inter alia, to provide a detection circuit that does not require a diaphragm between its movable object and its detectors.

Further objects of the invention are, inter alia, to provide to a detection arrangement, a device and a method that do not require a diaphragm.

The detection circuit according to the invention for detecting movements of a movable object comprises:

a first detector for detecting a first movement of the movable object in a first direction in a plane of the detection circuit, which first detector comprises a first detection unit for detecting a presence or an absence of a light spot at a location of the first detection unit, a location of the light spot depending on said first movement, and

a second detector for detecting a second movement of the movable object in a second direction perpendicular to the plane of the detection circuit, an intensity of the light spot depending on said second movement, which second detector comprises a second detection unit for detecting a first intensity or a second intensity of the light spot at a location of the second detection unit, the first and second intensities being different intensities unequal to zero.

By detecting at a first location a presence or an absence of a light spot, for example a horizontal movement of the movable object can be detected. By detecting at a second location an intensity of the light spot, for example a vertical movement of the movable object can be detected, and it is no longer necessary to use a diaphragm.

The detection circuit according to the invention is further advantageous, inter alia, in that it is less sensitive to misalignment of components during an assembly and simpler to produce and less costly.

An embodiment of the detection circuit according to the invention is defined by further comprising:

a third detector for detecting a third movement of the movable object in a third direction in the plane of the detection circuit, which third detector comprises a third detection unit for detecting a presence or an absence of the light spot at a location of the third detection unit, the location of the light spot depending on said third movement, the first and third directions being non-parallel directions.

The respective first and second and third directions are for example x and y and z directions in case of the plane of the detection circuit being a horizontal plane, without excluding further options.

An embodiment of the detection circuit according to the invention is defined by the first detector comprising further first detection units and the third detector comprising further third detection units, the first detection units being aligned parallel to the first direction and the third detection units being aligned parallel to the third direction. A plurality of first detection units and a plurality of third detection units allow the movements in the first and third directions to be detected more accurately. The pluralities of first and third detection units are for example lines of a cross, with the second detection unit being located at the crossing or close to the crossing or with a plurality of second detection units being located close to the crossing, at the line or lines of the cross or close to the lines of the cross.

An embodiment of the detection circuit according to the invention is defined by the second detector being entirely located within the light spot independently from a position of the movable object and the first and third detectors being partly located within the light spot dependently on the position of the movable object. The size of the light spot is preferably such that all second detection units of the second detector are located within this light spot independently from the position of the movable object and is preferably such that all second detection units of the second detector are located partly within this light spot and partly outside this light spot dependently on the position of the movable object. The position of the movable object determines a location of the light spot at the detection circuit.

An embodiment of the detection circuit according to the invention is defined by further comprising:

a source for generating a light signal, the movable object comprising a reflector for reflecting the light signal to the detection circuit, the light spot resulting from the reflected light signal.

By locating the source such as a light emitting source or an infrared light emitting heat source in the detection circuit and by providing the movable object with a reflector, it is no longer necessary to disadvantageously locate a source into the movable object.

An embodiment of the detection circuit according to the invention is defined by the first detection unit comprising a first photo element for generating a first photo element signal, which first photo element is coupled to a first transistor for digitizing the first photo element signal, and the second detection unit comprising a second photo element for generating a second photo element signal, which second photo element is coupled to a second transistor for digitizing the second photo element signal. By digitizing the photo element signals immediately behind the photo elements, such as photo diodes or photo transistors, complex and expensive analog-to-digital converters and amplifiers are avoided.

An embodiment of the detection circuit according to the invention is defined by the detection circuit being an integrated detection circuit based on at least one technique of a thin film poly silicon technique and a single crystal silicon substrate technique and a light emitting diode technique and an organic light emitting diode technique. Such an integrated circuit may advantageously comprise the photo elements, the transistors and the source, to form one robust circuit.

The detection arrangement according to the invention comprises the detection circuit according to the invention and further comprises the movable object.

An embodiment of the detection arrangement according to the invention is defined by the detection arrangement being a diaphragm-less arrangement. Such a diaphragm only introduces disadvantages.

An embodiment of the detection arrangement according to the invention is defined by the first movement of the movable object in the first direction in the plane of the detection circuit resulting from the movable object being tilted and the second movement of the movable object in the second direction perpendicular to the plane of the detection circuit resulting from the movable object being pushed down. The tilting and pushing down are user-friendly movements.

The device according to the invention comprises the detection circuit according to the invention and further comprises a man-machine-interface that comprises the movable object.

An embodiment of the device according to the invention is defined by the man-machine-interface further comprising a display, which display is an integrated display comprising the detection circuit. This way, the movable object forms for example part of the display and does not need to be built separately, which makes a production easier and less costly. The movable object may for example be located on a margin of a display area of the integrated display.

Embodiments of the detection arrangement according to the invention and of the device according to the invention and of the method according to the invention correspond with the embodiments of the detection circuit according to the invention.

The invention is based upon an insight, inter alia, that a diaphragm is to be used in case one kind of detector has to detect two different kinds of movements, and is based upon a basic idea, inter alia, that different kinds of detectors are to be used for detecting different kinds of movements.

The invention solves the problem, inter alia, to provide a detection circuit that does not require a diaphragm between its movable object and its detectors. The detection circuit according to the invention is further advantageous, inter alia, in that it is less sensitive to misalignment of components during an assembly and simpler to produce and less costly.

These and other aspects of the invention will be apparent from and elucidated with reference to the embodiments(s) described hereinafter.

In the drawings:

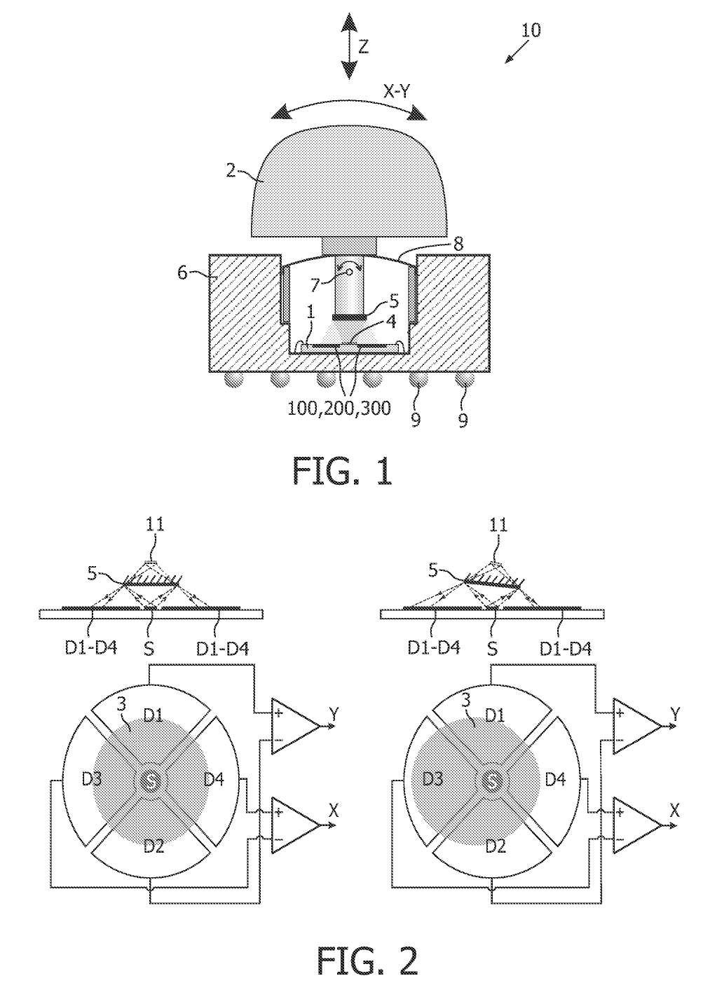

FIG. 1 shows diagrammatically a detection arrangement according to the invention in cross section,

FIG. 2 shows a detection circuit in cross section and in top view for a non-moved movable object (left side) and for a moved movable object (right side),

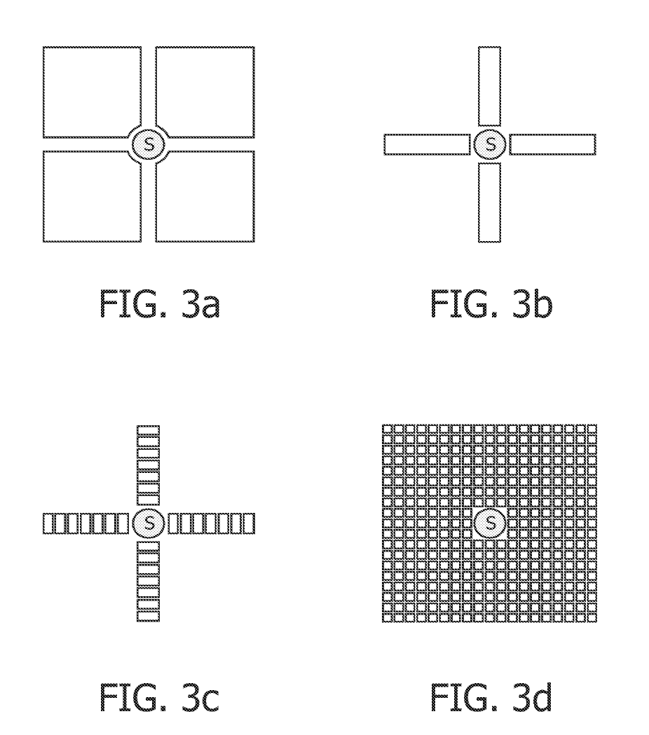

FIG. 3 shows detector layouts for a detection circuit according to the invention in top view,

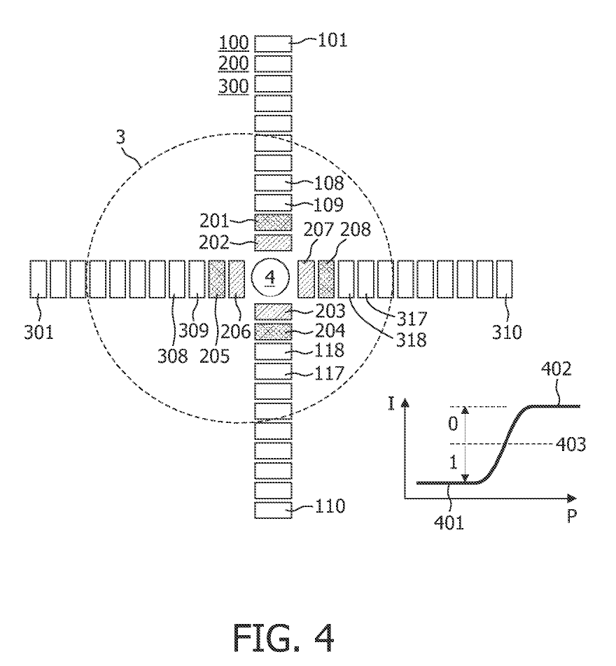

FIG. 4 shows a detector layout in greater detail for a detection circuit according to the invention in top view,

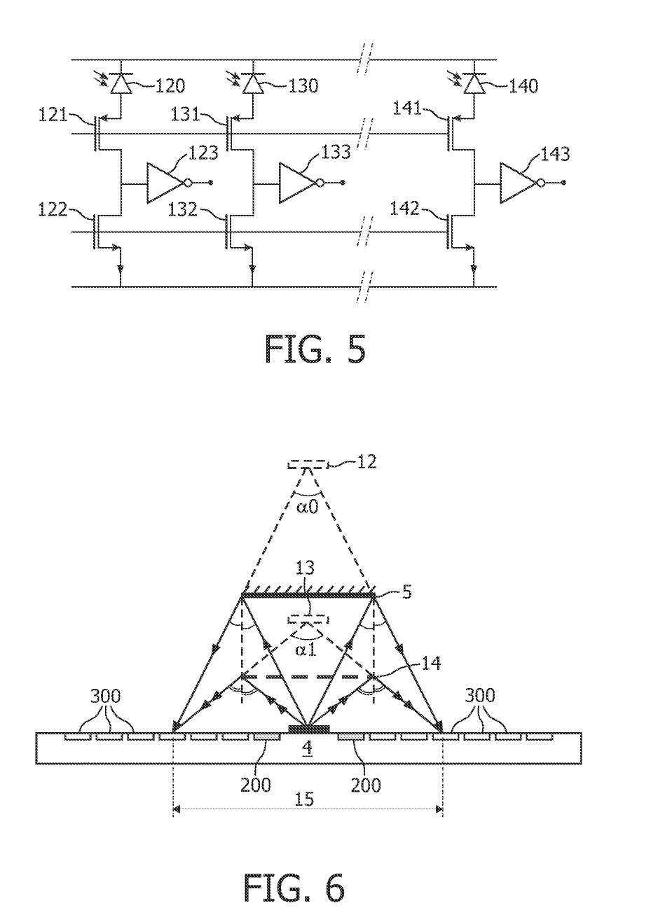

FIG. 5 shows photo diodes and transistors of a detection circuit according to the invention,

FIG. 6 shows a detector layout in greater detail for a detection circuit according to the invention in cross section,

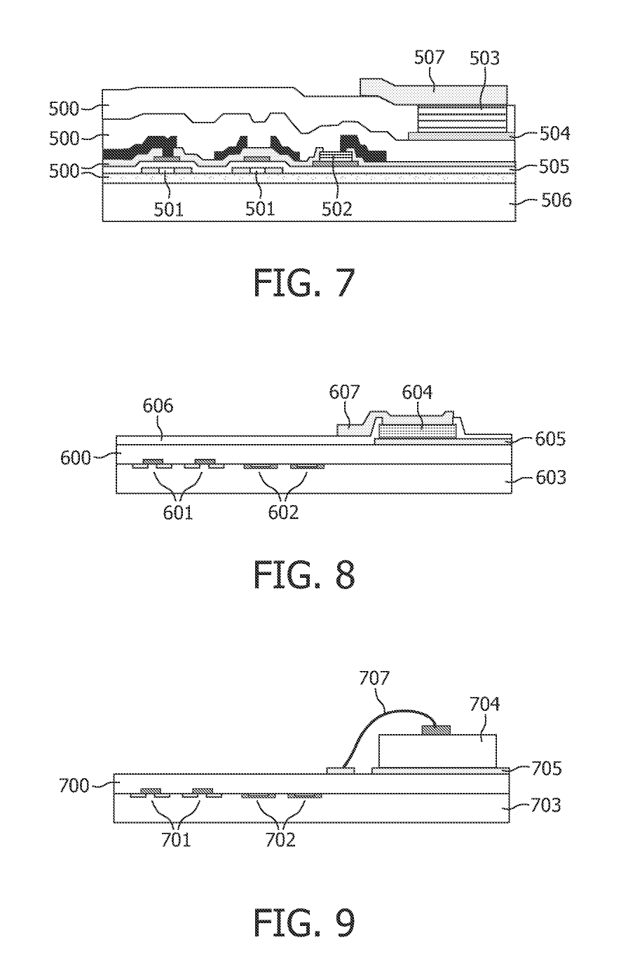

FIG. 7 shows a first integrated detection circuit according to the invention in cross section,

FIG. 8 shows a second integrated detection circuit according to the invention in cross section,

FIG. 9 shows a third integrated detection circuit according to the invention in cross section, and

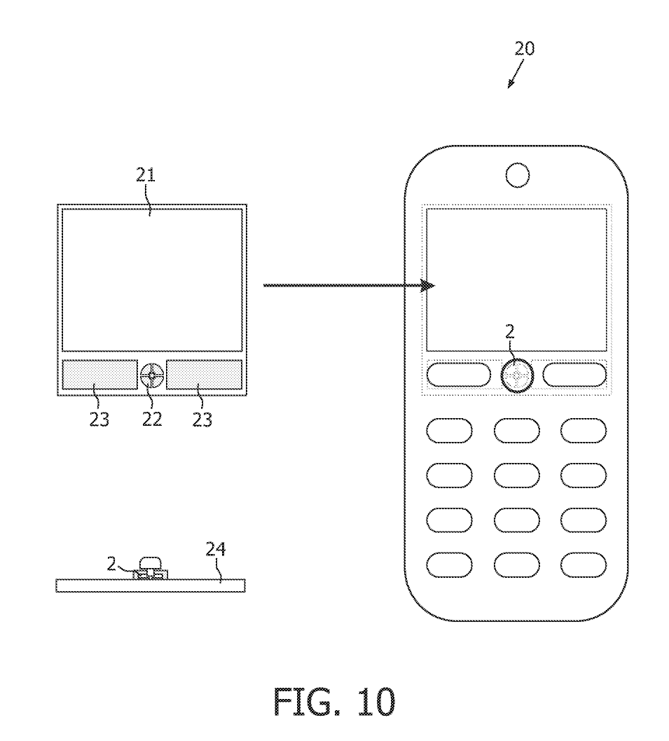

FIG. 10 shows a device according to the invention.

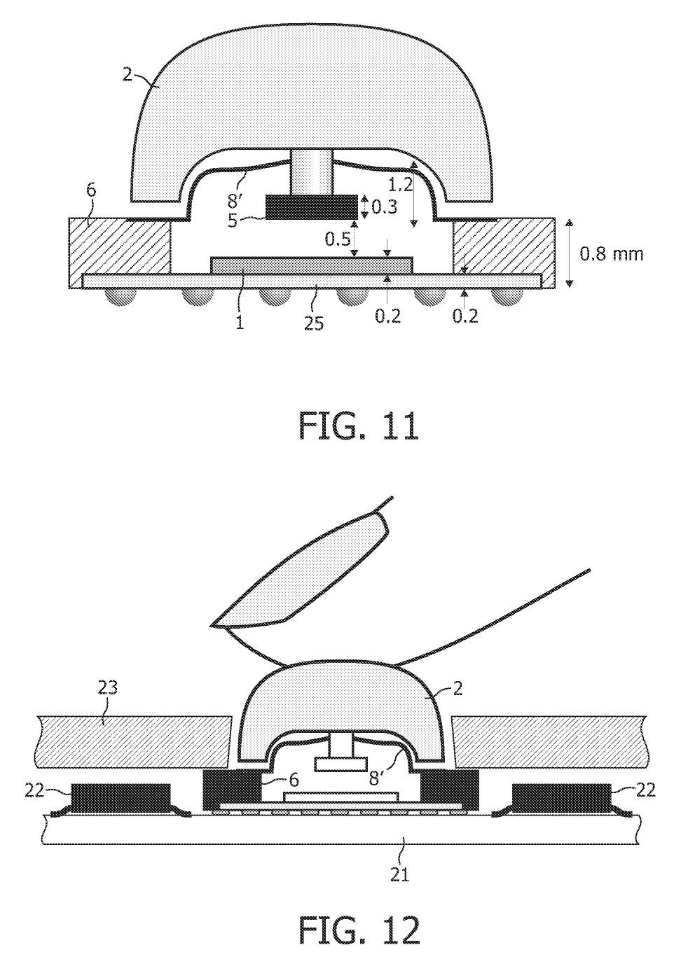

FIG. 11 shows an alternative detection arrangement according to the invention.

FIG. 12 shows a device with the alternative detection arrangement of FIG. 11.

The detection arrangement 10 according to the invention shown in the FIG. 1 in cross section comprises a detection circuit 1 according to the invention. The detection circuit 1 such as for example an ASIC die comprises detectors 100,200,300 such as for example photo diodes and a source 4 such as for example a light source like any kind of LED and is located in a package 6. A spring 8 is attached to the package 6, and a movable object 2 is coupled to the spring 8. This movable object 2 comprises a reflector 5 and a virtual rotation point 7. Solder balls 9 of the package 6 allow the package 6 to be connected to for example a device 20 shown in the FIG. 10. Further, x and y and z directions are shown in the FIG. 1.

The detection circuit 1 shown in the FIG. 2 in cross section and in top view for a non-moved movable object (left side) and for a moved movable object (right side) discloses in the cross sections, to explain a basic principle of the detection circuit 1, the detectors D1-D4 and the source S and an image 11 of the source S at an other side of the reflector 5. In the top views, the four detectors D1-D4 are shown surrounding the source S. Signals from the detectors D1 and D2 are subtracted from each other via a differential circuit to get a y direction signal and signals from the detectors D3 and D4 are subtracted from each other via a differential circuit to get an x direction signal.

When the movable object 2 such as a joystick is in a non-moved position or rest position (left side), the reflector 5 is parallel to the substrate and light emitted from the source S is reflected by the reflector 5 and casts a light spot 3 back onto the substrate. In other words the image 11 of the source S behind the reflector 5 shines a light cone through an opening created by the reflector's outline. The size of the reflector 5, the distance between the source S and the reflector 5 and the dimension of the detectors D1-D4 may be chosen such that the light spot 3 covers approximately half of the detectors area. Due to the symmetry of the system, the reflected light spot 3 is centered on the detectors D1-D4. In other words, all detectors D1-D4 are equally exposed to light and therefore the output signals in X and Y directions are zero.

When the joystick is tilted slightly to the right around a virtual pivot in the middle of or above the reflector 5, the image 11 is moved along a circle or a curve to a new position. The light cone is therefore also tilted and consequently the light spot 3 is displaced to the left and slightly elongated. Now the symmetry is broken: D3 receives more light than D4 while D1 and D2 are still equally shined. On the output X, a non-zero signal is detected which is proportional to the tilt angle of the joystick in the X direction; while the signal on the output Y remains zero. Similarly, a tilt in any direction (X and Y) can be detected by all four detectors D1-D4. The mentioned way of connecting the detectors D1-D4 is only an example. There exist different ways to extract the X and Y signals from the four detectors D1-D4.

In another implementation, the tilt of the joystick to a certain direction, thus the X and Y signals, are translated into the speed of a cursor on a display moving towards that direction. By tilting the joystick a user is able to move the cursor into a desired direction. The speed of the movement depends on the tilt angle. To stop the movement, the user needs to release the joystick and let it return to the rest position.

The detector layouts shown in the FIG. 3 for a detection circuit 1 according to the invention in top view are examples only, such as squares in the FIG. 3a or thin strips in the FIG. 3b and the number of the detectors can be more than four in the FIGS. 3c and 3d. In the FIG. 3c, there are a number of small detectors aligning along four sides of the source. By counting the number of detectors which are covered by the light spot, X and Y signals can be obtained. This FIG. 3c is shown in greater detail in the FIG. 4. In the FIG. 3d, the substrate contains a source S surrounded by an array of small detectors. The shape and position of the light spot which is corresponding to the tilt of the joystick, can be precisely determined by counting and locating the detector elements that are covered by the light spot.

In addition, but not shown, the reflector may have different shapes. The reflector can be a concave mirror. A distance between a central point of the mirror and the source may preferably be between f and 2f, where f is the focal length of the mirror. In this case, the reflected light spot on the substrate is significantly smaller than in the case of a flat mirror. The concave mirror is preferably used in combination with arrays of detectors as shown in the FIG. 3d. Due to the small size of the light spot, the position of the light spot, thus corresponding to the tilt of the joystick, can be more precisely determined.

The detector layout shown in the FIG. 4 in greater detail in top view for a detection circuit 1 according to the invention comprises a first detector 100 comprising for example 18 detection units 101-118 and comprises a second detector 200 comprising for example 8 detection units 201-208 and comprises a third detector 300 comprising for example 18 detection units 301-318. In an x direction from left to right the detection units 301-309 are followed by the detection units 205 and 206, by the source 4, by the detection units 207 and 208 and by the detection units 318-310. In a y direction from above to below the detection units 101-109 are followed by the detection units 201 and 202, by the source 4, by the detection units 203 and 204 and by the detection units 118-110. Further the light spot 3 is shown.

In addition, a graph disclosing an intensity I versus a position P is shown. A dark area is indicated by 401, a threshold is indicated by 403 and a lit area is indicated by 402. In this example, a logical “1” is generated for the dark area and a logical “0” is generated for the lit area.

The photo diodes 120,130,140 and the transistors 121,122,131,132,141,142 of a detection circuit 1 according to the invention are shown in the FIG. 5. Cathodes of the photo diodes 120,130,140 are coupled to a first reference terminal, and their anodes are coupled to first main electrodes of the transistors 121,131,141. Second main electrodes of these transistors 121,131,141 are coupled to first main electrodes of the transistors 122,132,142 and are coupled to inputs of inverters 123,133,143. The transistors 121,131,141 digitize the signal changes and the inverters 123,133,143 further digitize the signal and invert the digital signal. Second main electrodes of the transistors 122,132,142 are coupled to a second reference terminal. Control electrodes of the transistors 121,131,141 are coupled to each other. Control electrodes of the transistors 122,132,142 are coupled to each other. All control electrodes may be coupled to a further circuit for biasing purposes and for defining currents and for defining thresholds.

In fact for each group of detection units 101-109, 110-118, 301-309, 310-318, there may be a circuit as shown in the FIG. 5. About the detection units 201-208, in a minimum situation there will only be one detection unit, for example detection unit 201 or 202, in an extended situation there may be for example four detection units 201, 208, 204, 205 or 202, 203, 206, 207, and in a maximum situation there may be eight or more detection units. Independently of the number of detection units 201-208, each one may have its own circuit as shown in the FIG. 5 or two or more may have together a circuit as shown in the FIG. 5 etc.

The detection units 202,203,206,207 are for example used to detect a press-to-select (press in a Z direction) action, hereafter called the Z photo detectors. Alternatively, for example all detection units 201-208 may be Z photo detectors. The rest are used for X and Y detection, hereafter called X/Y photo detectors. The Z photo detectors are preferably inside the light spot, regardless the position of the joystick. The positions of the Z photo detectors can be changed, for example a little more away from the source, and/or not in line with the X/Y photo detectors.

In a detection circuit, a signal of each X/Y photo detector is compared to a corresponding reference signal, which results in a one bit digital signal. For instance if the X-Y photo detector is outside the light spot, the circuit shown in the FIG. 5 results in a “1” for this photo detector, or in the other case, if the photo detector is inside the light spot, the circuit results in a “0”. The circuit is actually a one bit ADC (analog-to-digital converter). In other words, the circuit is a threshold detection (see the inset on the corner of FIG. 4). For instance when the border of the light spot travels across a photo detector, a light intensity received on the photo detector is increased from the dark value 401 to the lit value 402. Somewhere in the middle of these two levels, a threshold 403 is defined. That means when the border of the light spot travels about half way across the photo detector, the signal received on the detector should be switched from “1” (dark) to “0” (lit). In a later stage a digital circuit counts the number of photo diodes which are exposed to the light spot in each group, which represents the signal in that group. Signals X and Y will then be calculated by subtracting (digitally) signals of group 3 to group 4 and signals of group 1 to group 2, respectively. The advantage of this digital detection method is that the electronic circuits are simpler. No analog circuits such as amplifiers and ADCs are required. The signals are digitalized right at every photo detector.

The photo detectors such as photo diodes are reverse biased and for example connected in a current mirror circuit not shown. Via this current mirror circuit, a reference current may be defined. This reference current is mirrored to create equal and separate currents running through the photo diodes in the same group. Depending on the luminance condition of a photo diode 120, the middle point, for example the coupling between the transistors 121 and 122, can be at a low or a high value. For instance, when the photo diode is not lit, a voltage at this point is almost zero, but when the photo diode is exposed to light, its internal resistance drastically decreases (exponentially with a light intensity), that makes the point switching quickly to a high value. To ensure a fully digitalized signal, an extra threshold detection circuit such as an inverter e.g. 123 can be added. Finally at the output of each inverter, a digital signal can be obtained, which depends on the luminance condition of the photodiode. The outputs from the photo diodes in each group can be in a later stage fed into an encoder to have it converted into a binary number. Other suitable circuits than the encoder can be used as well.

The detector layout shown in the FIG. 6 in greater detail in cross section for a detection circuit 1 according to the invention discloses the detectors 200 and 300 and the source 4 and the reflector 5 and an image 12 of the source 4 in a non-moved position or rest position of the reflector 5 and the reflector 5 at a moved position or non-rest position 14 and an image 13 of the source 4 for this moved position or non-rest position and a light spot dimension 15.

When the joystick is pressed vertically, to for example select a certain item on a display as shown in the FIG. 10, the diameter of the spot of the reflected light on the substrate is not changed, but the light intensity of the spot is increased. In the beginning the reflector 5 is in the rest position. The light beams reflected at the edges of the reflector define the boundary of the reflected light spot on the substrate. This phenomenon can also be considered in an equivalent way: The image 12 of the light source (which is symmetrical to the source over the reflector), shines a light cone through an imaginary hole in the place of the reflector 5. The solid angle of the cone in this case is α0. Given a fixed luminance power of the source, the light intensity on the substrate is proportional to α0/A, where A is the area of the reflected light spot.

Now if the joystick is pressed vertically (click action), the reflector is supposed to travel to position 14 which is closer to the substrate than before. Applying a simple reflection rule, one can easily see that the size of the reflected light spot does not grow, but stays the same. However, due to the fact that the image 13 of the source now gets closer to the reflector, the solid angle α1 of the light cone is now larger than α0. Consequently, the light intensity received by the substrate (˜α1/A, with A unchanged) is also increased. One or more Z photo detectors (e.g. 4) will sense this change and with a simple threshold detection circuit, a digital signal, corresponding to the vertical position of the stick, is generated. In principle, only one Z photo detector is necessary. However, to ensure a symmetrical movement of the stick, more than one Z photo detector (for instance 2-4) is to be preferred. The Z photo detectors can be arranged in the same rows as the X/Y photo detectors, or they can be located elsewhere, preferably provided that they are inside the light spot, regardless the position of the stick.

FIG. 7 shows a first integrated detection circuit 1 according to the invention in cross section. The light source 503 is an Organic Light Emitting Diode (OLED) which is deposited and patterned onto a substrate 506, which contains electronic devices such as thin film transistors (TFTs) 501, photo diodes 502, etc. based on a Low Temperature Poly-Silicon (LTPS) technique. The TFTs or LTPS photo diodes if not shielded are sensitive to light, therefore can be used as photo detectors. Besides, electronic circuits based on LTPS can be used to control and do signal processing for the device, that makes the device completely integrated. LTPS and OLED technologies have recently been combined on one common substrate to make the active-matrix OLED displays. Therefore, the use of this technique for the optical pointing device is an advantage in terms of technology reuse, high degree of integration and low-cost. The wavelength of the OLED can be chosen to suit the sensitive range of the LTPS-based photo detectors. Isolation layers are indicated by 500, a transparent top electrode is indicated by 507, a bottom electrode is indicated by 504, gate oxide is indicated by 505.

FIG. 8 shows a second integrated detection circuit 1 according to the invention in cross section. Si photo diodes 602 (used as photo detectors) and CMOS circuits 601 can be integrated on a single crystal Si substrate 603. After the Si wafer is complete (after back-end-of-the-line process), the wafer is transferred to an OLED fab where an OLED structure is deposited and patterned on top of the Si wafer. The wafer is then diced into separated dies for use in for example an optical pointing device. A transparent top electrode is indicated by 607, a bottom electrode is indicated by 605, an OLED is indicated by 604, an interconnection of the Si die is indicated by 600 and an isolation layer is indicated by 606.

FIG. 9 shows a third integrated detection circuit 1 according to the invention in cross section. Si photo diodes 702 (used as photo detectors) and CMOS circuits 701 can be integrated on a Si substrate 703. After the Si wafer is complete (after back-end-of-the-line process), inorganic LED dies 704 are mounted (by the pick-and-place process and gluing) on top of the Si wafer. The wafer is then diced into separated dies for use in the optical pointing device. A bond wire is indicated by 707, a bottom electrode is indicated by 705, an interconnection of the Si die is indicated by 700.

Because a heat source emits infrared light, it can be used as an infrared light source as well. The heat source can be created easily on Si substrate for instance by a resistive heater (using metal resistor or poly resistor). Alternatively, visual light or infrared light can be created on Si by using light emission of silicon P—N junctions, for instance when the P—N junction is reversed-bias and under avalanching conditions, or using the so-called “latch-up” phenomenon of the CMOS transistors. The latch-up is an undesired phenomenon in an ICs when too much current flowing inside a couple of transistors in a loop which creates heat and infrared emission. Latch-up happens due to improper design or defects of the chip. However in this case, latch-up is deliberately created. Si photo diodes are sensitive to infrared wavelength therefore can be used to detect the infrared light coming from the heat source.

FIG. 10 shows a device 20 according to the invention. It comprises a display 21 and a movable object 2 such as a joystick. The joystick is for example mounted on a joystick area 22 of the display area that comprises the detection circuit 1 and the source 4 between integrated electronics areas 23, which form part of a display substrate 24. The optical joystick is based on the active-matrix OLED display technology. The arrangement consists of an OLED light source and a number of photo detectors based on TFTs fabricated on a common substrate, and a joystick having a reflector, hung above the substrate. This arrangement can be used in devices such as mobile phones, PDAs and other handheld devices to navigate through the menus on the display. The detection circuit 1 may have any kind of detector layout, for example one of the layouts shown in the FIG. 3 or a combination thereof, without excluding further layouts.

A device for example contains a photonic die which is diced from a large substrate containing OLEDs, photo detectors and integrated electronics fabricated using the OLED display technology. As a supplement, the joystick may be integrated on an OLED display substrate and can be sold with the display, as an additional function of the display. In an OLED display in e.g. mobile phones, some margins surrounding the display area can be used for on-board electronics such as driving circuits of the display, connection pads, etc. at least some components for an optical joystick may be integrated in the margin of the display area, among other electronic circuits. The electronics of the joystick can also be integrated in the surrounding area of the display. The FIG. 10 right side shows the combined display-joystick in a mobile phone, for example. The body of joystick and its suspension mechanism can be built on the display substrate (see FIG. 10, bottom-left), or can be a part of the top cover of the phone.

For handheld devices the dimensions of the detection arrangement 10 are critical, because there is not much space available in e.g. a mobile phone. In particular the height of the detection arrangement should be as small as possible. The height of the detection arrangement in FIG. 1 is largely determined by the height of the suspension 8. FIG. 11 shows schematically a very advantageous alternative embodiment of the detection arrangement 10, wherein the space inside the movable object 2 in the form of a knob is used to house the suspension 8′. This measure can reduce the height significantly. The suspension 8′ protrudes from the package 6. Instead of being housed inside the package, it now resides inside the knob 2. The hollow space inside the knob should be sufficiently large to allow the movable object 2 (such as a joystick) to tilt and click without touching. This alternative embodiment allows to thin the package 6 thickness down to 1 mm or even 0.8 mm as shown in FIG. 11. The actual thickness of the package is more determined by the required mechanical strength of the package, rather than by the height of the components inside. The typical thickness of the package substrate 25 is about 0.2 mm and the thickness of the device substrate 1 is about 0.2 mm. Another advantage is that since a relatively large volume of the knob can be used to house the suspension 8′, the suspension design can be more relaxed in dimensions.

FIG. 12 shows a device 20 with the alternative detection arrangement of FIG. 11. The device 20 is here a mobile phone. The package 6 with the solder balls 9 is connected to a printed circuit board (PCB) 21. Other neighboring ICs on the PCB 22 may be present to provide other functionalities to the mobile phone. The knob 2 is embedded in a housing 23 of the mobile phone. The alternative detection arrangement can also be applied as a mouse pointer in notebooks, or as a pointing device on a display in mobile phones, PDAs, portable gaming devices, remote control and other handheld devices.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A detection circuit for detecting movements of a movable object, comprising:
a first detector for detecting a first movement of the movable object in a first direction in a plane of the detection circuit, wherein the first detector comprises a first detection unit for detecting a presence or an absence of a light spot at a location of the first detection unit, a location of the light spot depending on said first movement, and
a second detector for detecting a second movement of the movable object in a second direction perpendicular to the plane of the detection circuit, an intensity of the light spot depending on said second movement, wherein the second detector comprises a second detection unit for detecting a first intensity or a second intensity of the light spot at a location of the second detection unit, the first and second intensities being different intensities unequal to zero.

2. The detection circuit as defined in claim 1, further comprising:
a third detector for detecting a third movement of the movable object in a third direction in the plane of the detection circuit, wherein the third detector comprises a third detection unit for detecting a presence or an absence of the light spot at a location of the third detection unity, the location of the light spot depending on said third movement, the first and third directions being non-parallel directions.

3. The detection circuit as defined in claim 2, the first detector comprising further first detection units and the third detector comprising further third detection units, the first detection units being aligned parallel to the first direction and the third detection units being aligned parallel to the third direction.

4. The detection circuit as defined in claim 2, the second detector being entirely located within the light spot independently from a position of the movable object and the first and third detectors being partly located within the light spot dependent on the position of the movable object.

5. The detection circuit as defined in claim 1, further comprising:
a source for generating a light signal, the movable object comprising a reflector for reflecting the light signal to the detection circuit, the light spot resulting from the reflected light signal.

6. The detection circuit as defined in claim 1, the first detection unit comprising a first photo element for generating a first photo element signal, wherein the first photo element is coupled to a first transistor for digitizing the first photo element signal, and the second detection unit comprising a second photo element for generating a second photo element signal, wherein the second photo element is coupled to a second transistor for digitizing the second photo element signal.

7. The detection circuit as defined in claim 1, the detection circuit being an integrated detection circuit based on at least one technique of a thin film poly silicon technique and a single crystal silicon substrate technique and a light emitting diode technique and an organic light emitting diode technique.

8. (canceled)

9. (canceled)

10. (canceled)

11. A device comprising a detection circuit a man-machine-interface that includes a movable object, wherein the detection circuit includes:
a first detector for detecting a first movement of the movable object in a first direction in a plane of the detection circuit, wherein the first detector includes a first detection unit for detecting a presence or an absence of a light spot at a location of the first detection unit, a location of the light spot depending on said first movement; and
a second detector for detecting a second movement of the movable object in a second direction perpendicular to the plane of the detection circuit, an intensity of the light spot depending on said second movement, wherein the second detector comprises a second detection unit for detecting a first intensity or a second intensity of the light spot at a location of the second detection unit, the first and second intensities being different intensities unequal to zero.

12. The device as defined in claim 11, the man-machine-interface further comprising an integrated display that includes the detection circuit.

13. A method for detecting movements of a movable object via a detection circuit, comprising:
detecting a first movement of the movable object in a first direction in a plane of the detection circuit, detecting a presence or an absence of a light spot via a first detection unit at a location of the first detection unit, a location of the light spot depending on said first movement,
detecting a second movement of the movable object in a second direction perpendicular to the plane of the detection circuit, an intensity of the light spot depending on said second movement, detecting a first intensity or a second intensity of the light spot via a second detection unit at a location of the second detection unit, the first and second intensities being different intensities unequal to zero.
